(19) United States
(12) Patent Application Publication
(10) Pub. No.: US 2019/0312160 A1
(43) Pub. Date: Oct. 10, 2019

(54) METHOD FOR MANUFACTURING FINGER ELECTRODE FOR SOLAR CELL AND FINGER ELECTRODE FOR SOLAR CELL PREPARED THEREBY

(71) Applicant: SAMSUNG SDI CO., LTD., Yongin-si (KR)

(72) Inventors: Seok Hyun JUNG, Suwon-si (KR); Min Jae KIM, Suwon-si (KR); Chul Kyu KIM, Suwon-si (KR); Young Ki PARK, Suwon-si (KR); Sang Hyun YANG, Suwon-si (KR); Min Young LEE, Suwon-si (KR); Ryun Min HEO, Suwon-si (KR)

(21) Appl. No.: 16/207,519

(22) Filed: Dec. 3, 2018

(30) Foreign Application Priority Data
Apr. 9, 2018 (KR) 10-2018-0041155

(51) Int. Cl. H01L 31/0224; C09D 11/52; C09D 11/037

(52) U.S. Cl. CPC H01L 31/022425; C09D 11/037; C09D 11/52

(57) ABSTRACT

A method of manufacturing an electrode for a solar cell includes printing a conductive paste on a front surface of a substrate using a printing mask having an opening rate of 65% or more, and baking the printed conductive paste. The conductive paste may include a conductive powder, a glass fit, and an organic vehicle, the glass fit may include lithium oxide and tungsten oxide, and, in the glass fit, a weight ratio of lithium oxide to tungsten oxide may be about 0.5 to about 5.5.

### CROSS-REFERENCE TO RELATED APPLICATION

Korean Patent Application No. 10-2018-0041155, filed on Apr. 9, 2018, in the Korean Intellectual Property Office, and entitled: “Method for Manufacturing Finger Electrode for Solar Cell and Finger Electrode for Solar Cell Prepared Thereby,” is incorporated by reference herein in its entirety.

### BACKGROUND

### 1. Field

Embodiments relate to a method of manufacturing a finger electrode for solar cells and a finger electrode for solar cells manufactured by the same.

### 2. Description of the Related Art

Solar cells generate electricity using the photovoltaic effect of a p-n junction, which converts photons of sunlight into electricity. In a solar cell, front and rear electrodes are formed on upper and lower surfaces of a semiconductor wafer or substrate having a p-n junction, respectively. Then, the photovoltaic effect at the p-n junction is induced by sunlight entering the semiconductor wafer, and electrons generated by the photovoltaic effect at the p-n junction provide electric current to the outside through the electrodes.

Such a solar cell electrode is generally manufactured by placing a printing mask having openings for formation of electrodes on a semiconductor substrate, placing a conductive paste on the printing mask, and printing the conductive paste on the semiconductor substrate through the openings of the printing mask in the form of electrodes, followed by baking the printed conductive paste.

FIG. 1 shows an image of a general printing mask used in formation of a solar cell electrode.

Referring to FIG. 1, a general printing mask may be manufactured by applying a photosensitive resin 14 to a mesh 12 arranged obliquely with respect to the longitudinal direction of the printing mask and selectively removing a portion of the photosensitive resin 14 at which an electrode will be printed using a photoresist process, thereby forming an electrode printing portion 16. Such a general printing mask for formation of solar cell electrodes may have an opening rate of 45% to 60%, wherein the opening rate refers to the proportion of the area occupied by a mesh-free portion of the printing portion 16 relative to the total area of the electrode printing portion 16.

### SUMMARY

Embodiments are directed to a method of manufacturing an electrode for a solar cell, the method including printing a conductive paste on a front surface of a substrate using a printing mask having an opening rate of 65% or more; and baking the printed conductive paste. The conductive paste may include a conductive powder, a glass fit, and an organic vehicle, the glass frit may include lithium oxide and tungsten oxide, and, in the glass frit, a weight ratio of lithium oxide to tungsten oxide may be about 0.5 to about 5.5.

The printing mask may include a mesh, a photosensitive resin layer integrated with the mesh, and an electrode printing portion formed by removing the photosensitive resin layer. The printing mask may have an opening rate of about 65% to about 90%.

The lithium oxide may be present in an amount of about 1 wt % to about 10 wt % in the glass frit.

The tungsten oxide may be present in an amount of about 1 wt % to about 10 wt % in the glass frit.

The glass fit may further include one or more of lead oxide, zinc oxide, tellurium oxide, magnesium oxide, bismuth oxide, sodium oxide, molybdenum oxide, or silicon oxide.

The conductive paste may include about 60 wt % to about 95 wt % of the conductive powder, about 0.5 wt % to about 10 wt % of the glass frit, and about 1 wt % to about 30 wt % of the organic vehicle.

The conductive paste may further include one or more of a dispersant, a thixotropic agent, a plasticizer, a viscosity stabilizer, an anti-foaming agent, a pigment, a UV stabilizer, an antioxidant, or a coupling agent.

The opening rate may be calculated according to the following equation:

{(Area of electrode printing portion−Area occupied by mesh in electrode printing portion)/Area of electrode printing portion}×100.

The lithium oxide may be Li₂O, and the tungsten oxide may include WO₂, WO₃, W₂O₃, W₂O₅, or a combination thereof.

Embodiments are also directed to an electrode for a solar cell manufactured by a method according to an embodiment.

Embodiments are also directed to a solar cell including an electrode according to an embodiment.

### BRIEF DESCRIPTION OF DRAWINGS

Features will become apparent to those of skill in the art by describing in detail example embodiments with reference to the attached drawings in which:

FIG. 1 illustrates a view of a general printing mask used in formation of a finger electrode for solar cells.

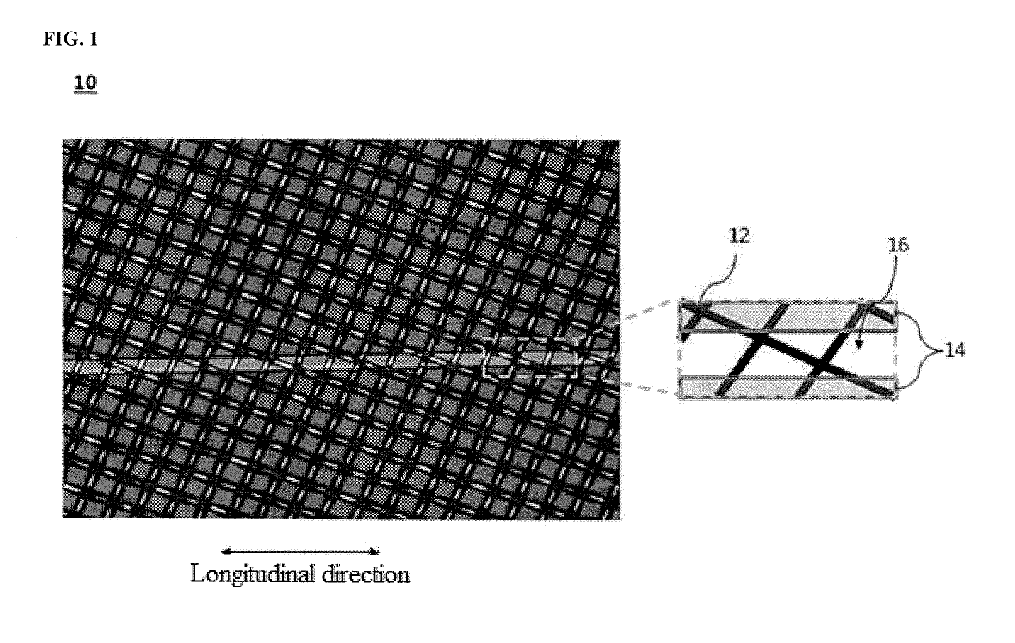

FIG. 2 illustrates a view of a printing mask having a high opening rate according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

A method for manufacturing a finger electrode for solar cells according to an example embodiment includes: printing a conductive paste on a front surface of a substrate using a printing mask having an opening rate of 65% or more; and baking the printed conductive paste, wherein the conductive paste includes a conductive powder, a glass frit, and an organic vehicle and, in the glass frit, a weight ratio of lithium (Li) oxide to tungsten (W) oxide (lithium oxide/tungsten oxide) ranges from about 0.5 to about 5.5.

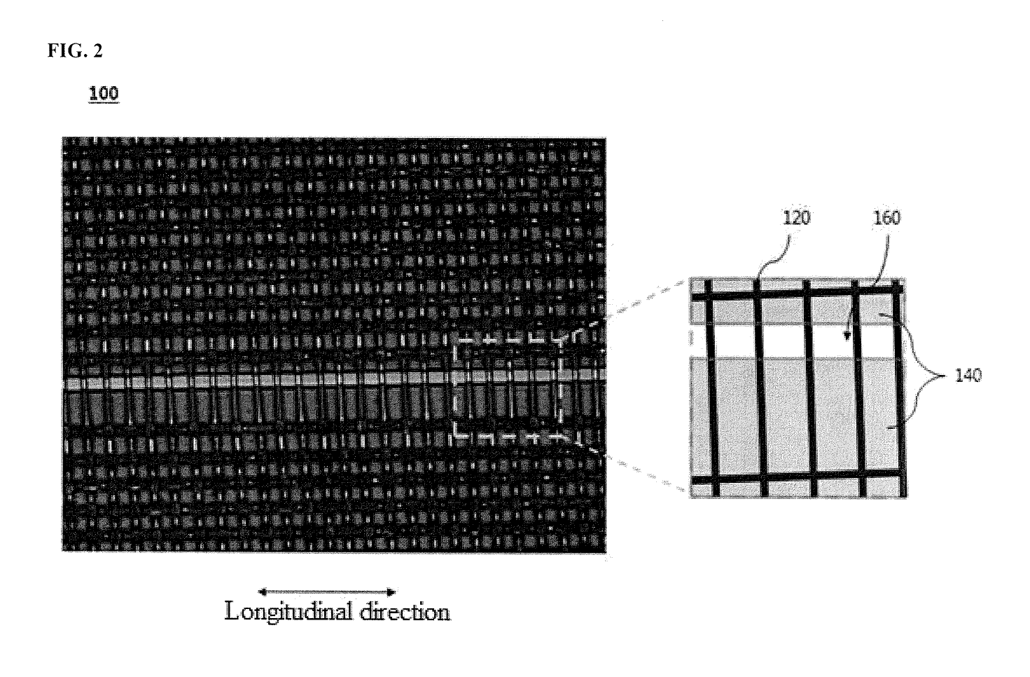

First, the printing mask according to an example embodiment will be described with reference to FIG. 2.

FIG. 2 shows a printing mask 100 according to an example embodiment. Referring to FIG. 2, the printing mask 100 includes a mesh 120, a photosensitive resin layer 140 integrated with the mesh 120, and an electrode printing portion 160 formed by removing a portion of the photosensitive resin layer. The opening rate of the printing mask is calculated according to Equation 1:

Opening rate (%)={(Area of electrode printing portion−Area occupied by mesh in electrode printing portion)/Area of electrode printing portion}×100 [Equation 1]

According to the present example embodiment, the printing mask 100 has a high opening rate, for example, an opening rate of about 65% or more, for example, about 65% to about 90%.

A finger electrode manufactured using the printing mask 100 including the electrode printing portion having a high opening rate may have a reduced linewidth. In addition, the conductive paste may be prevented from spreading after printing or bleeding during baking, thereby improving the aspect ratio of the electrode.

In the printing mask 100, warp threads of the mesh may be arranged at an angle of about 80° to 105°, for example, 85° to 100°, with respect to a longitudinal direction of the printing mask. When the angle of the warp threads of the mesh falls within this range, the area occupied by the mesh in the electrode printing portion may be reduced and a high opening rate may be provided.

In addition, as shown in FIG. 2, the distance between weft threads of the mesh above and below the electrode printing portion 160 may be longer than the distance between weft threads of the mesh in the other region. When the distance between the weft threads of the mesh adjacent the electrode printing portion is relatively long, the area occupied by the mesh in the electrode printing portion 160 may be reduced while avoiding a reduction in printability due to tension applied to the printing mask by a pressing means during printing of the conductive paste.

Next, an example of the conductive paste used in the present example embodiment will be described.

The conductive paste may include a conductive powder, a glass frit, and an organic vehicle.

Conductive Powder

The conductive powder may be or include a conductive powder having an average particle diameter (D50) of about 0.1 μm to about 10 μm. Within this range, the conductive powder may improve the aspect ratio and electrical properties of an electrode. The average particle diameter (D50) may be measured using, for example, a Model 1064D particle size analyzer (CILAS Co., Ltd.) after dispersing the conductive powder in isopropyl alcohol (IPA) at 25° C. for 3 minutes via ultrasonication. The conductive paste may include one type of conductive powder or two or more types of conductive powders having different average particle diameters (D50).

The conductive powder may include a suitable conductive powder for solar cell electrodes, such as silver, aluminum, nickel, copper, or a combination thereof, etc. For example, silver powder may be selected in terms of electrical properties.

The conductive powder may have various particle shapes, such as a spherical, flake or amorphous particle shape, etc.

The conductive powder may be present in an amount of about 60 wt % to about 95 wt % in the conductive paste. Within this range, the conductive paste may improve conversion efficiency of a solar cell and may be easily prepared in paste form.

Glass Frit

The glass frit helps to form silver crystal grains in an emitter region by etching an anti-reflection layer and melting the conductive powder during a baking process of the electrode paste. Further, the glass frit helps improve adhesion of the conductive powder to a wafer and is softened to decrease the baking temperature during the baking process.

When sheet resistance of a solar cell is increased in order to improve solar cell efficiency, this may tend to increase solar cell contact resistance and leakage current. Thus, it is desired to minimize both serial resistance (Rs) and influence on a p-n junction while maximizing open circuit voltage. In addition, as the baking temperature varies within a broad range with increasing use of various wafers having different sheet resistances, it is desirable that the glass frit secure sufficient thermal stability to withstand a wide range of baking temperatures.

According to the present example embodiment, the glass frit includes lithium oxide and tungsten oxide in a weight ratio of lithium oxide to tungsten oxide of, for example, about 0.5 to about 5.5. Within this range, an electrode formed of the conductive paste may exhibit good electrical properties while having a fine linewidth even when manufactured using a printing mask having a high opening rate of about 65% or more. A weight ratio of lithium oxide to tungsten oxide may range from about 0.8 to about 5.0, for example, about 0.9 to about 4.5.

The lithium oxide may be present in an amount of about 1 wt % to about 10 wt %, for example, about 2 wt % to about 8 wt %, in the glass frit. Within this range, the glass frit may be easily prepared, and the conductive paste may realize fine electrode linewidth and reduce resistance of a solar cell.

The tungsten oxide may be present in an amount of about 1 wt % to about 10 wt %, for example, about 1 wt % to about 8 wt %, in the glass frit. Within this range, the glass frit may be easily prepared, and the conductive paste may realize a fine electrode linewidth and have good adhesion.

A total amount of the lithium oxide and the tungsten oxide in the glass frit may range from about 5 wt % to about 20 wt %, for example, about 7 wt % to about 15 wt %. Within this range, an electrode formed of the conductive paste may be easily controlled in aspect ratio and may exhibit good electrical properties, and may have a fine linewidth when a printing mask having a high opening rate of about 65% or more is used.

The lithium oxide may be Li₂O. The tungsten oxide may include at least one of WO₂, WO₃, W₂O₃, and W₂O₅. For example, the tungsten oxide may be or include WO₃.

In an example embodiment, the glass frit may further include at least one of lead (Pb), zinc (Zn), tellurium (Te), magnesium (Mg), bismuth (Bi), sodium (Na), molybdenum (Mo), and silicon (Si), and/or oxides thereof.

For example, lead (Pb) or an oxide thereof may be present in an amount of about 1 wt % to about 40 wt %, for example, about 5 wt % to about 30 wt %, in the glass fit. For example, zinc (Zn) or an oxide thereof may be present in an amount of about 1 wt % to about 20 wt %, for example, about 5 wt % to about 20 wt %, in the glass fit. For example, tellurium (Te) or an oxide thereof may be present in an amount of about 30 wt % to about 80 wt %, for example, about 35 wt % to about 75 wt %, in the glass fit. For example, magnesium (Mg) or an oxide thereof may be present in an amount of about 0.01 wt % to about 5 wt %, for example, about 0.01 wt % to about 1 wt %, in the glass frit. For example, bismuth (Bi) or an oxide thereof may be present in an amount of about 20 wt % or less, for example, about 5 wt % to about 20 wt %, in the glass fit. For example, sodium (Na) or an oxide thereof may be present in an amount of about 5 wt % or less, for example, about 0.01 wt % to about 1 wt %, in the glass fit. For example, molybdenum (Mo) or an oxide thereof may be present in an amount of about 5 wt % or less, for example, about 0.01 wt % to about 5 wt %, in the glass frit. For example, silicon (Si) or an oxide thereof may be present in an amount of about 1 wt % or less, for example, about 0.01 wt % to about 1 wt %, in the glass frit. When the amounts of the aforementioned metals or oxides thereof fall within these ranges, the conductive paste may exhibit good adhesion and may help improve electrical properties of an electrode.

The glass frit may further include at least one of phosphorus (P), germanium (Ge), gallium (Ga), cerium (Ce), iron (Fe), boron (B), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), and aluminum (Al) oxides.

The glass fit may be prepared from the aforementioned metal or oxides thereof by a suitable method. For example, the aforementioned metal or oxides thereof may be mixed in a predetermined ratio using a ball mill or a planetary mill. The mixture may then be melted, for example, at about 900° C. to about 1300° C., followed by quenching to about 25° C. The resulting material may be subjected to pulverization using a disk mill, a planetary mill, or the like, thereby preparing a glass frit.

The glass frit may be prepared to have an average particle diameter (D50) of about 0.1 μm to about 10 μm, and may have a spherical or amorphous shape. The average particle diameter (D50) of the glass frit may be measured in the same manner as that of the conductive powder.

The glass fit may be present in an amount of about 0.5 wt % to about 10 wt %, for example, about 1 wt % to about 7 wt %, in the conductive paste. Within this range, the glass frit may secure stability of a p-n junction under various sheet resistances, minimize serial resistance, and improve solar cell efficiency.

Organic Vehicle

The organic vehicle may be used to impart suitable viscosity and rheological characteristics for printing to the composition for solar cell electrodes, and may be combined using mechanical mixing with inorganic components of the composition.

The organic vehicle may be a suitable organic vehicle used in a composition for solar cell electrodes and may include, for example, one or more of a binder resin, a solvent, or the like.

The binder resin may be selected from, for example, acrylate resins or cellulose resins. Ethyl cellulose may be used as the binder resin. In another implementation, the binder resin may be or include one or more of, for example, ethyl hydroxyethyl cellulose, nitrocellulose, blends of ethyl cellulose and phenol resins, alkyd resins, phenol resins, acrylate ester resins, xylene resins, polybutane resins, polyester resins, urea resins, melamine resins, vinyl acetate resins, wood rosin, polymethacrylates of alcohols, or the like. These may be used alone or as mixtures thereof.

The solvent may be or include one or more of, for example, hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, or ethyl lactate. These may be used alone or as mixtures thereof.

The organic vehicle may be present in an amount of, for example, about 1 wt % to about 30 wt % in the conductive paste. Within this range, the organic vehicle may provide good printability to the conductive paste.

Additive

The conductive paste according to an example embodiment may further include a suitable additive to enhance fluidity, process properties, stability, etc. The additive may be or include one or more of a dispersant, a thixotropic agent, a plasticizer, a viscosity stabilizer, an anti-foaming agent, a pigment, a UV stabilizer, an antioxidant, a coupling agent, or the like. These may be used alone or as mixtures thereof. The additive may be present in an amount of, for example, about 0.1 wt % to about 5 wt % based on the total weight of the composition.

Printing the conductive paste may be performed through a procedure in which, after the printing mask having an opening rate of 65% or more is disposed on the front surface of the substrate and the conductive paste is disposed on the printing mask, a pressing element such as a squeegee or a roller is moved on the conductive paste such that the conductive paste is printed on the front surface of the substrate through openings of the printing mask.

Then, the conductive paste may be subjected to drying at, for example about 150° C. to about 400° C., for example, about 200° C. to about 400° C. Drying may be performed in an IR drying furnace or the like. In addition, drying may be performed for, for example, about 10 to 120 seconds.

Then, the printed conductive paste may be subjected to baking, thereby forming a finger electrode. Baking may be performed at, for example, about 600° C. to 1000° C. for about 10 to 120 seconds.

Finger Electrode for Solar Cells

A finger electrode for solar cells according to an example embodiment may be manufactured by s method of manufacturing a finger electrode for solar cells according to an example embodiment.

The finger electrode for solar cells may have a small linewidth of, for example, about 50 μm or less, for example, about 20 μm to about 50 μm, for example, about 20 μm to about 48 μm, and thus may increase a light receiving area, thereby helping to realize high conversion efficiency of a solar cell.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### PREPARATIVE EXAMPLES

Details of components used in the following Preparative Examples are as follows:

(A) Conductive powder: Spherical silver (Ag) powder having an average particle diameter (D50) of 2.0 μm (4-11F, Dowa Hightech Co., Ltd.)

(B) Glass frit: Glass frits (average particle diameter (D50): 2.0 μm) listed in Table 1 (wt %)

(C) Organic binder: Ethylcellulose (STD4, Dow Chemical Company)

(D) Solvent: Texanol (2,2,4-Trimethyl-1,3-pentanediol monoisobutyrate) (Eastman Chemical Company)

(E) Dispersant: TEGO® Dispers 656 (Evonik Industries)

(F) Thixotropic agent: Thixatrol ST (Elementis Co., Ltd.)

### Preparative Example 1

For Preparative Example 1, 1.5 wt % of the organic binder (C) was dissolved in 6.0 wt % of the solvent (D) at 60° C. to prepare an organic vehicle, and then 89 wt % of the conductive powder (A), 2.5 wt % of a glass frit (Preparative Example 1 in Table 1), 0.5 wt % of the dispersant (E), and 0.5 wt % of the thixotropic agent (F) were added to the organic vehicle, followed by mixing and kneading in a 3-roll kneader, thereby preparing a conductive paste. The glass frit of Preparative Example 1 was prepared by mixing metal oxides in a weight ratio set forth in Table 1 (unit: wt %).

### Preparative Examples 2 to 17

For Preparative Examples 2 to 17, conductive pastes were prepared in the same manner as in Preparation Example 1 except that glass frits listed in Table 1 were used instead of the glass frit of Preparative Example 1.

TABLE 1

| Preparative | | | | | | | | | | | Weight |
|---|---|---|---|---|---|---|---|---|---|---|---|
| Example | PbO | Bi₂O₃ | TeO₂ | Li₂O | Na₂O | ZnO | WO₃ | MoO₃ | MgO | SiO₂ | ratio |
| 1 | 5.54 | 19.27 | 46.21 | 6.92 | — | 15.49 | 5.75 | — | 0.82 | — | 1.20 |
| 2 | 6.33 | — | 60.33 | 7.91 | — | 17.70 | 6.57 | — | 0.47 | 0.69 | 1.20 |
| 3 | 5.47 | — | 73.04 | 5.13 | 0.05 | 9.98 | 5.68 | — | 0.05 | 0.60 | 0.90 |
| 4 | 14.34 | 5.30 | 56.30 | 6.53 | — | 11.69 | 4.46 | 0.78 | 0.60 | — | 1.46 |
| 5 | 14.72 | 5.44 | 52.33 | 6.71 | — | 14.79 | 4.58 | 0.80 | 0.63 | — | 1.47 |
| 6 | 13.53 | 14.17 | 51.85 | 6.16 | — | 11.03 | 1.47 | 1.40 | 0.39 | — | 4.19 |
| 7 | 14.36 | 5.30 | 58.37 | 6.55 | — | 11.70 | 1.56 | 1.85 | 0.31 | — | 4.20 |
| 8 | 28.36 | 4.98 | 42.27 | 5.20 | 0.43 | 13.54 | 4.19 | 0.73 | 0.30 | — | 1.24 |
| 9 | 26.90 | 13.39 | 37.11 | 5.16 | — | 12.84 | 3.98 | 0.27 | 0.35 | — | 1.30 |
| 10 | 27.34 | 13.61 | 39.53 | 5.92 | — | 10.59 | 1.41 | 1.20 | 0.40 | — | 4.20 |
| 11 | 27.70 | 5.35 | 42.05 | 6.60 | — | 14.55 | 1.57 | 1.87 | 0.31 | — | 4.20 |
| 12 | 5.45 | 8.17 | 47.17 | 5.56 | — | 15.22 | 16.87 | 0.76 | 0.80 | — | 0.33 |
| 13 | 5.73 | 8.64 | 61.14 | 5.84 | — | 16.01 | 0.99 | 0.80 | 0.85 | — | 5.90 |
| 14 | 5.89 | 6.11 | 63.51 | 6.00 | — | 16.45 | — | 0.82 | 0.87 | 0.35 | — |
| 15 | 20.61 | 1.33 | 44.40 | 5.06 | — | 11.90 | 16.05 | 0.28 | 0.37 | — | 0.32 |
| 16 | 21.62 | 1.39 | 57.56 | 5.31 | — | 12.49 | 0.94 | 0.29 | 0.40 | — | 5.65 |
| 17 | 21.81 | 1.40 | 57.81 | 5.35 | — | 12.60 | — | 0.30 | 0.40 | 0.33 | — |

*In Table 1, the weight ratio refers to the weight ratio of Li₂O/WO₃ in each glass frit.

### EXAMPLES

### Example 1

A printing mask having an opening rate of 82% and including an electrode printing portion having a linewidth of 26 μm (Samlip Precision Ind.) was placed on a semiconductor substrate, and the conductive paste prepared in Preparative Example 1 was placed on the printing mask and then printed using a squeegee, followed by drying in an IR drying furnace. Then, an aluminum paste was printed on a back surface of the semiconductor substrate and dried in the same manner as above. Cells formed according to this procedure were subjected to baking at 950° C. for 45 seconds in a belt-type baking furnace, thereby fabricating a solar cell.

### Examples 2 to 11 and Comparative Examples 1 to 6

Solar cells were fabricated in the same manner as in Example 1 except that conductive pastes listed in Table 2 were used instead of the conductive paste of Preparative Example 1.

### Comparative Example 7

A solar cell was fabricated in the same manner as in Example 1 except that a printing mask having an opening rate of 63% and including an electrode printing portion having a linewidth of 26 μm (Murakami Co., Ltd.) was used.

Property Evaluation

The solar cells fabricated in Examples 1 to 11 and Comparative Examples 1 to 7 were evaluated as to the following properties. Results are shown in Table 2.

(1) Linewidth and thickness: Electrode linewidth and thickness were measured using a confocal microscope (VK-9700, Keyence Corp.).

(2) Electrical properties: Each of the solar cells prepared in Examples 1 to 11 and Comparative Examples 1 to 7 was evaluated as to short circuit current (Isc), open-circuit voltage (Voc), contact resistance (Rs), fill Factor (FF), and conversion efficiency (Eff.) using a solar cell efficiency tester (CT-801, Pasan Co., Ltd.).

TABLE 2

| | | Linewidth | Thickness | | Voc | | | |
|---|---|---|---|---|---|---|---|---|
| Item | Paste | (μm) | (μm) | Isc (A) | (mV) | Rs (Ω) | FF (%) | Eff. (%) |
| Ex. 1 | Prep. Ex. 1 | 33.5 | 16.7 | 9.420 | 0.6414 | 0.0029 | 79.0 | 19.97 |
| Ex. 2 | Prep. Ex. 2 | 34.3 | 15.6 | 9.419 | 0.6409 | 0.0028 | 79.0 | 19.95 |
| Ex. 3 | Prep. Ex. 3 | 33.0 | 14.2 | 9.426 | 0.6419 | 0.0029 | 78.9 | 19.97 |
| Ex. 4 | Prep. Ex. 4 | 38.0 | 14.1 | 9.417 | 0.6418 | 0.0030 | 79.1 | 20.00 |
| Ex. 5 | Prep. Ex. 5 | 37.7 | 14.1 | 9.417 | 0.6421 | 0.0029 | 78.9 | 19.96 |
| Ex. 6 | Prep. Ex. 6 | 38.3 | 14.6 | 9.413 | 0.6411 | 0.0029 | 78.9 | 19.92 |
| Ex. 7 | Prep. Ex. 7 | 37.5 | 14.0 | 9.418 | 0.6424 | 0.0029 | 78.9 | 19.97 |
| Ex. 8 | Prep. Ex. 8 | 40.4 | 15.3 | 9.411 | 0.6425 | 0.0028 | 79.1 | 20.01 |
| Ex. 9 | Prep. Ex. 9 | 36.7 | 15.4 | 9.418 | 0.6427 | 0.0028 | 79.0 | 20.01 |
| Ex. 10 | Prep. Ex. 10 | 40.2 | 15.3 | 9.413 | 0.6421 | 0.0030 | 79.0 | 19.98 |
| Ex. 11 | Prep. Ex. 11 | 40.8 | 15.7 | 9.409 | 0.6416 | 0.0028 | 78.8 | 19.90 |
| Comp. | Prep. Ex. 12 | 41.9 | 16.2 | 9.393 | 0.6419 | 0.0032 | 78.3 | 19.75 |
| Ex. 1 | | | | | | | | |
| Comp. | Prep. Ex. 13 | 41.4 | 15.4 | 9.394 | 0.6395 | 0.0031 | 78.5 | 19.73 |
| Ex. 2 | | | | | | | | |
| Comp. | Prep. Ex. 14 | 43.4 | 15.3 | 9.390 | 0.6415 | 0.0038 | 77.5 | 19.53 |
| Ex. 3 | | | | | | | | |
| Comp. | Prep. Ex. 15 | 41.4 | 14.7 | 9.390 | 0.6410 | 0.0034 | 78.7 | 19.82 |
| Ex. 4 | | | | | | | | |
| Comp. | Prep. Ex. 16 | 38.8 | 14.8 | 9.399 | 0.6402 | 0.0033 | 78.5 | 19.76 |
| Ex. 5 | | | | | | | | |
| Comp. | Prep. Ex. 17 | 44.9 | 14.7 | 9.387 | 0.6398 | 0.0039 | 78.0 | 19.60 |
| Ex. 6 | | | | | | | | |
| Comp. | Prep. Ex. 1 | 34.1 | 12.3 | 9.432 | 0.6413 | 0.0067 | 74.7 | 18.91 |
| Ex. 7 | | | | | | | | |

As shown in Table 2, it can be seen that the solar cell electrodes of Examples 1 to 11, each prepared using a printing mask having an opening rate set forth herein and a conductive paste according to an example embodiment, had a high aspect ratio while exhibiting good electrical properties.

Conversely, the solar cell electrodes of Comparative Examples 1 to 6, each prepared using a printing mask having an opening rate according to an example embodiment and a conductive paste including a glass frit in which the content ratio between metal oxides was outside the range set forth herein, had large linewidths and exhibited poor electrical properties.

In addition, for the solar cell electrode of Comparative Example 7, prepared using the conductive paste according to an example embodiment and a printing mask having a low opening rate, the paste could not be smoothly injected due to the low opening rate of the printing mask during the printing process, causing severe pattern disconnection and increase in solar cell resistance.

By way of summation and review, a finger electrode may be formed on a front surface of a solar cell to have a small linewidth and a large height so as to increase a sunlight receiving area. However, when a general printing mask having an opening rate of 45% to 60% is used, the ability to increase the electrode aspect ratio (height/linewidth) may be limited, and improvement in solar cell conversion efficiency may thus be limited.

Consideration has been given to increasing the aspect ratio of a finger electrode using a printing mask having an opening rate of 65% or more. However, when a general conductive paste composition, such as that used in a general process using a printing mask having a low opening rate, is applied to a printing mask having a high opening rate, the linewidth may be increased during baking, which may result in little or no increase in aspect ratio, and/or resulting in deterioration in electrical properties.

As described above, embodiments may provide a method of manufacturing a finger electrode for solar cells, which may have a fine linewidth and a high aspect ratio and exhibit good electrical properties, and a finger electrode for solar cells manufactured by the same.

According to an example embodiment, a method of manufacturing a finger electrode for solar cells may use a printing mask having an opening rate of 65% or more and a conductive paste, and may provide a finger electrode for solar cells having a fine linewidth and a high aspect ratio and exhibiting good electrical properties.

### LIST OF REFERENCE NUMERALS

10, 100: printing mask
12, 120: mesh
14, 140: photosensitive resin layer
16, 160: electrode printing portion

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing an electrode for a solar cell, the method comprising:
printing a conductive paste on a front surface of a substrate using a printing mask having an opening rate of 65% or more; and
baking the printed conductive paste, wherein:
the conductive paste includes a conductive powder, a glass frit, and an organic vehicle,
the glass frit includes lithium oxide and tungsten oxide, and
in the glass frit, a weight ratio of lithium oxide to tungsten oxide is about 0.5 to about 5.5.

2. The method as claimed in claim 1, wherein the printing mask includes a mesh, a photosensitive resin layer integrated with the mesh, and an electrode printing portion formed by removing the photosensitive resin layer, the printing mask having an opening rate of about 65% to about 90%.

3. The method as claimed in claim 1, wherein the lithium oxide is present in an amount of about 1 wt % to about 10 wt % in the glass fit.

4. The method as claimed in claim 1, wherein the tungsten oxide is present in an amount of about 1 wt % to about 10 wt % in the glass frit.

5. The method as claimed in claim 1, wherein the glass frit further includes one or more of lead oxide, zinc oxide, tellurium oxide, magnesium oxide, bismuth oxide, sodium oxide, molybdenum oxide, or silicon oxide.

6. The method as claimed in claim 1, wherein the conductive paste includes about 60 wt % to about 95 wt % of the conductive powder, about 0.5 wt % to about 10 wt % of the glass frit, and about 1 wt % to about 30 wt % of the organic vehicle.

7. The method as claimed in claim 1, wherein the conductive paste further includes one or more of a dispersant, a thixotropic agent, a plasticizer, a viscosity stabilizer, an anti-foaming agent, a pigment, a UV stabilizer, an antioxidant, or a coupling agent.

8. The method as claimed in claim 1, wherein the opening rate is calculated according to the following equation:
{(Area of electrode printing portion−Area occupied by mesh in electrode printing portion)/Area of electrode printing portion}×100.

9. The method as claimed in claim 1, wherein the lithium oxide is Li₂O, and the tungsten oxide includes WO₂, WO₃, W₂O₃, W₂O₅, or a combination thereof.

10. An electrode for a solar cell manufactured by the method as claimed in claim 1.

11. A solar cell including the electrode as claimed in claim 10.
